(19) United States
(12) Patent Application Publication
(10) Pub. No.: US 2006/0192592 A1
(43) Pub. Date: Aug. 31, 2006

(54) Circuit arrangement and method for data transmission

(76) Inventors: Robert Inderst, Pocking (DE); Dieter Speiser, Kissing (DE)

Correspondence Address: SIEMENS CORPORATION;INTELLECTUAL PROPERTY DEPARTMENT, 170 WOOD AVENUE, SOUTH, ISELIN, NJ, 08830, US

(21) Appl. No.: 11/351,069

(22) Filed: Feb. 9, 2006

(30) Foreign Application Priority Data
Feb. 10, 2005 (DE) 10 2005 006 172.9

(51) Int. Cl. H03K 5/19

(52) U.S. Cl. 327/24

(57) ABSTRACT

With the circuit arrangement and the associated method a start or announcement signal indicating a data transmission is sampled with a module-specific clock and on detection of the beginning of a start signal sent along with the payload data to be transmitted, the payload data to be transmitted is forwarded synchronously with the module-specific clock to the downstream processing units.

### CROSS REFERENCE TO RELATED APPLICATIONS

This application claims priority of German application No. 102005006172.9 DE filed Feb. 10, 2005, which is incorporated by reference herein in its entirety.

### FIELD OF INVENTION

The present invention relates to a circuit arrangement and method for data transmission.

### BACKGROUND OF INVENTION

Time-consuming protocol and synchronization procedures are often required to enable data or data packets to be transmitted between modules at separate locations. In addition the connecting lines between the modules at separate locations must be the same length in each case and subject to particular screening.

### SUMMARY OF INVENTION

An object of the invention is to specify a further circuit arrangement and a method for data transmission.

The object is achieved by the claims, such that for a circuit arrangement and a method for data transmission between a first and a second module with separate clock supply units, a synchronization module is provided with an edge detection unit with downstream evaluation unit for detecting and selecting a beginning of a start signal sent separately in parallel to a data transmission, with the edge detection unit featuring a sampling module with a least one sampling unit to detect the beginning of the start signal.

The invention brings with it the advantage that within a half clock period data is synchronized to a module-specific clock signal and thereafter a data transmission to the relevant module can be started.

The invention brings with it the advantage that no screening or adherence to exact line lengths between the modules is needed.

The invention brings with it the advantage that data packets with any given number of bytes can be transmitted.

The invention brings with it the advantage that an earliest possible sampling point for the data to be transmitted allows a rapid and secure beginning of data transmission.

The invention brings with it the advantage that transmission without data loss is ensured.

The invention brings with it the further advantage that no redesign of modules or subracks is needed since a synchronization unit to be implemented can easily be integrated into an existing module.

The invention brings with it the advantage that the data packets can be transmitted quasi-synchronously with the data rate of half the clock frequency. To sample a signal at least double the frequency is necessary. This is to be the clock frequency of the receiving module. The transmission can thus advantageously be undertaken with the half clock frequency. For these signals the transmission paths then only need to meet small requirements, e.g. not equal in length, no screening.

The invention brings with it the advantage that a window is formed on the receiver module in which the data packets to be transmitted are clocked in.

The window is formed again and for each new data packet. This has the advantage that a window determined always has the optimum location in relation to the associated data packet. Since the clock pulses of the two modules do not possess any stable position in relation to each other the window can also assume a new position for each new data packet. This window is subsequently used to securely and precisely accept each data word of a data packet. It brings with it the further advantage that the data can be transmitted with half clock frequency and not slower through the window.

The invention also brings with it the advantage that delay time differences of the data bits of a start signal and a valid signal can be very largely ignored.

### BRIEF DESCRIPTION OF THE DRAWINGS

The invention will be explained in greater detail with reference to an exemplary embodiment.

The figures show:

FIG. 1 a block diagram for data transmission between two modules,

FIG. 2 a block diagram of a synchronization module,

FIG. 3 an embodiment of the synchronization module,

FIG. 4 associated pulse diagrams and

FIG. 5 a further pulse diagram.

### DETAILED DESCRIPTION OF INVENTION

With the circuit arrangement and the associated method a sampling of a start or announcement signal indicating a data transmission is undertaken with a module-specific clock and on recognition of the start of an additional start signal sent with the user data to be transmitted, the user data to be transmitted is forwarded synchronously with the module-specific clock to subsequent processing units.

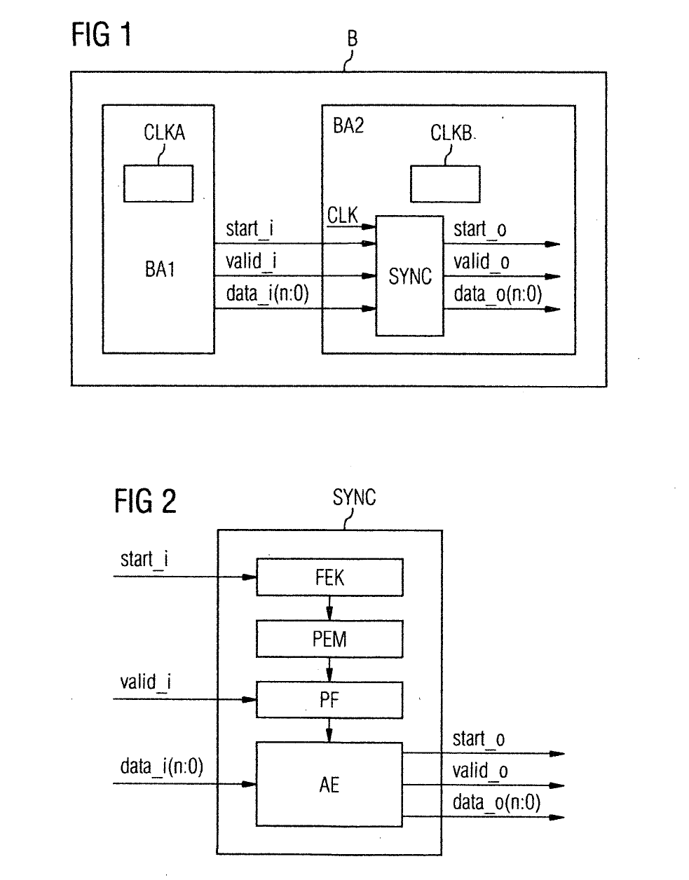

FIG. 1 shows a circuit arrangement in accordance with the invention. This typical arrangement is formed with modules BA1, BA2 at separate locations. In this case, starting from a first module BA1, data is transmitted via at least one data line which is not shown in any greater detail here, for example in the form of data packets, to a second module BA2. The first module BA1 has a first clock supply unit CLKA which is independent of the rack and of a second module BA2. The second module BA2 has a second clock supply unit CLKB. The clock frequency of the clock signal of the first and the second clock supply unit CLKA, CLKB is almost the same.

A synchronization module SYNC is arranged between the first module BA1 and the second module BA2. This synchronization unit SYNC can be arranged at or in the immediate vicinity of the second module BA2. The first module BA1 is connected to the synchronization unit SYNC of the second module BA2 by at least one data connection on which a start signal start_i, a valid signal valid_i and the data/data packets to be transmitted are transmitted. The output signals of the synchronization unit SYNC are forwarded directly or indirectly to the second module BA2. One advantage of this design lies in the fact that if the lines are routed differently between the first and the second module BA1, BA2, or between the first module BA1 and the synchronization unit SYNC respectively, it is not necessary to ensure that the line lengths are the same. Furthermore the arrangement brings with it the advantage that the data lines do not have to be screened, as is usually the case with such a high data rate. Screening is specifically required for clock signals. Faults on such lines can lead to the edge-controlled modules attached to them (e.g. flip-flops, etc.) performing uncontrolled switching processes under some circumstances. Faults on data lines by contrast are rather less critical since such signals do not as a rule initiate any active switching processes but are merely evaluated at a secure point in time. One of the advantages of the invention is that a clock signal does not have to be transmitted along with the data. The screening can thus be dispensed with.

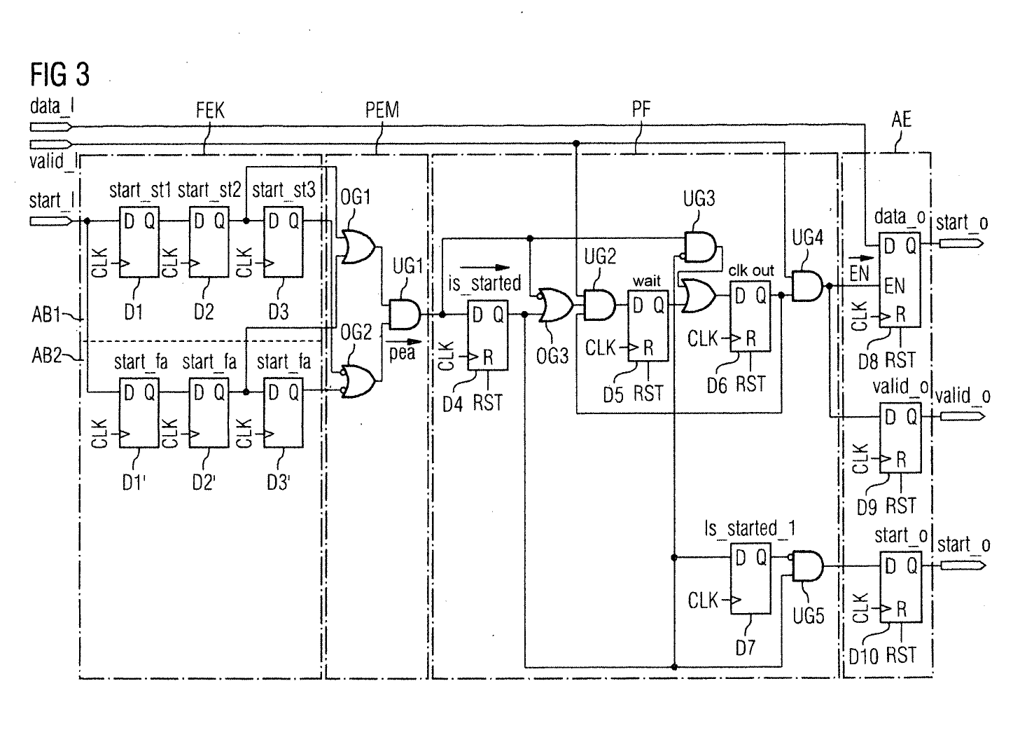

FIG. 2 shows a block diagram of individual modules FEK, PEM, PF and AE which are arranged in a synchronization unit SYNC. This block diagram is shown in FIG. 3 with a possible circuit design.

The synchronization unit SYNC shown in detail in FIG. 3 features an edge detection module FEK, an evaluation module which can also be called a pulse discrimination module PEM, a pulse shaping module PF and an output unit AE.

On the input side an input signal start_i, valid_i and data_i is present at the synchronization unit. The first input signal start_i can extend over one or more CLK periods and signals the beginning of a data transmission. The second input signal valid_i signals that data packets are available for transmission. The third input signal is a schematic image of the data or data packets to be transmitted.

The first input signal start_i is applied to the edge detection module FEK arranged on the input side in the synchronization unit SYNC.

The edge detection module FEK is made up of a first and a second sampling unit AB1, AB2. These sampling units can each be formed by edge-controlled components connected serially to one another with double clocking or synchronization.

The first input signal start_i is synchronized in the edge detection module FEK by double sampling. The leading edge of the first input signal start_i can in this case be selected by the leading or trailing edge of the clock signal CLK.

A first sampling unit AB1 can, as shown in FIG. 3, be embodied from input edge-triggered D flip-flops D1, D2, and D3. With a leading edge of the clock signal CLK, this first series circuit forwards the first input signal start_i, which can also be called a start signal, present at its input to the subsequent D flip-flops D2, D3.

A second sampling unit AB2 is likewise formed from input edge-triggered D flip-flops D1′, D2′, D3′ and in each case forwards the start signal start_i present at its input with a trailing edge of the clock signal CLK.

The first input edge-triggered D flip-flop D1, D1′ of the sampling unit AB1, AB2 is used for a synchronization of the first input signal start_i to the clock signal of the second module.

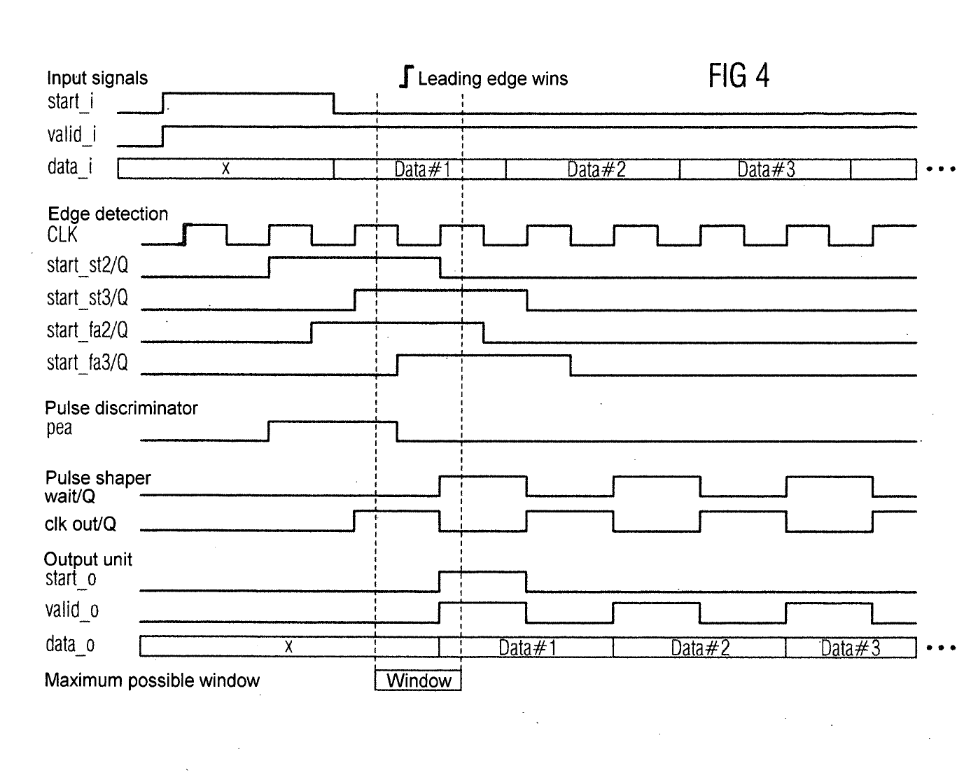

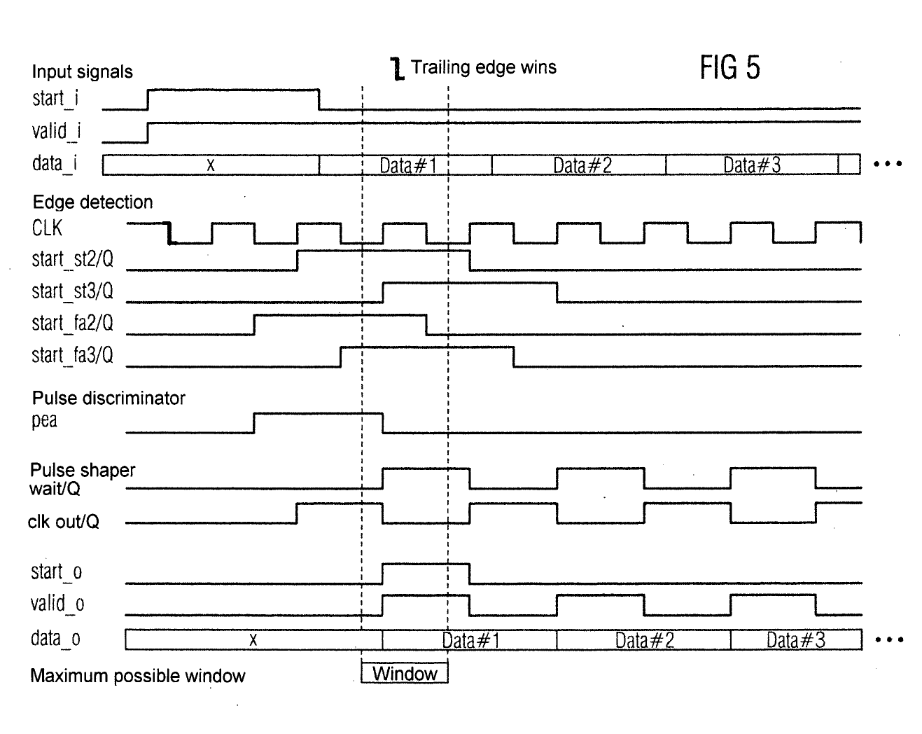

In the pulse discrimination module PEM, which is also called the evaluation unit, input signal states along the first and the second sampling unit AB1, AB2 of the edge detection module FEK are tapped and combined. To this end the output signals of the second D flip-flop D2, D2′ and the output signals of the third D flip-flop D3, D3′ are each logically combined via OR gates OG1, OG2, with the output signals of the third D flip-flop D3, D3′ being logically combined negated at the input of the second OR gate OG2. The output signals of the OR gates OG1, OG2 are present at the inputs of the AND gate UG1. The output signal pea of the pulse discrimination module PEM thus produced is forwarded, as shown in FIGS. 4 and 5, for further processing to the pulse shaping module PF.

In the pulse discrimination module PEM a search is made for the change of edge in signal start_i. The design of the circuit brings with it the advantage that the change of edge in the first input signal start_i is selected at the latest after a half clock period of the clock signal CLK and a secure acceptance of the data signals data_i can be initiated by downstream processing units of the second module BA2. The secure detection of the first input signal start_i can in this case be undertaken with first edge change in the clock signal CLK. The output signal pea of the pulse discrimination unit PEM is formed by a pulse with a width of at least one clock period, see FIGS. 4, 5. As shown in FIG. 3, the occurrence or a first change of edge in the first input signal start_i is registered in the pulse discrimination module PEM by a first OR gate OG, to this end the output signal of the input edge triggered D flip-flop D2 and D2′ is applied to the first OR gate OG1 in each case. A second OR gate OG2 ensures that only the first edge change in the first input signal start_i will be evaluated. This edge change of the first input signal start_i can be selected at a leading edge of the clock signal CLK or at the trailing edge of the clock signal CLK. If there is a new edge change of the input signal start_i this will be filtered out by the OR gate OG2. Please refer to FIGS. 4 and 5.

The pulse shaping module PF is for example made up of further input edge-triggered D flip-flops D4, D5, D6 and D7 and gate chips OG3, UG2, UG3, UG4 and UG5. The functions of these components can also be emulated by components with equivalent functions.

The components used can be replaced as long as the logical equivalence is ensured.

In the pulse shaping module PF a detected edge change in a first input signal start_i is clocked out in the input edge-triggered D flip-flop D4 with the clock signal CLK. The output signal of D4 marks the start of the acceptance of the data to be transmitted data_i. After each clock pulse a wait pulse is inserted. This is the result of the fact that the transmission is undertaken with the half clock frequency of the receiving module.

The input edge-triggered D flip-flop D4 in this case delivers an is_started signal with the pulse duration of two clock periods CLK. The input edge-triggered D flip-flop D7, in conjunction with the downstream AND gate UG5 in synchronization with the enable signal EN delivers a start signal start_o to the output unit AE.

The output unit AE forwards the signals data_o, valid_o and start_o in accordance with the clock signal CLK to downstream processing units.

The output unit AE is for example formed from further edge-triggered D flip-flops D8, D9 and D10. On the output side, after application of the enable signal EN issued by the pulse shaping unit PF, the data signal data_o is present at the first input edge-triggered D flip-flop D8 synchronous to the clock signal CLK.

The second input edge-triggered D flip-flop D9 signals to subsequent processing units a presence or absence of a data signal. With the third input edge-triggered D flip-flop D10 the start of the data transmission is signaled to the subsequent processing units.

Based on the fact that, with optimum sampling, the beginning of the data packets can vary through a jitter, the sampling point within the window provided for it is predetermined.

FIGS. 4 and 5 show the signal sequences of the synchronization unit already discussed above in relation to each other.

1.-8. (canceled)

9. A circuit arrangement for data transmission between a first module with a first clock supply unit and a second module with a second clock supply unit, comprising:
a synchronization module comprising
an edge detection unit having a sampling unit for detecting a beginning of a start signal, and
an evaluation unit downstream from the edge detection unit, the evaluation unit selecting the beginning of the start signal sent in parallel with a data transmission.

10. The circuit according to claim 9,
wherein the edge detection unit includes a first sampling unit and a second sampling unit, and
wherein the first and second sampling units are formed from a series circuit with input edge-triggered logic elements.

11. The circuit in accordance with claim 10,
wherein the first and second sampling units comprise a first, second and third D flip-flop,
wherein an edge change occurs within a leading edge of a second clock supply unit signal for the first sampling unit, and
wherein the edge change occurs within a trailing edge of the second clock supply unit signal for the second sampling unit.

12. The circuit in accordance with claim 11,
wherein the evaluation unit comprises a first, second and third logic elements for selecting a first edge,
wherein the first logic element detects an edge change in the start signal, and
wherein the second logic element filters out a further edge change in the start signal.

13. The circuit in accordance with claim 12,
wherein inputs of the first logic element are connected to receive the output signals of the second D flip-flops, and
wherein inputs of the second logic element are connected to receive outputs signals of the third D flip-flops.

14. The circuit in accordance with claim 13,
wherein the first logic element is an or gate, and
wherein the second logic element is a nor gate.

15. The circuit in accordance with claim 9,
wherein the evaluation unit comprises a first, second and third logic elements for selecting a first edge,
wherein the first logic element detects an edge change in the start signal, and
wherein the second logic element filters out a further edge change in the start signal.

16. The circuit according to claim 9, wherein the evaluation unit detects an edge change in the start signal with a first logic element and detects a further edge change with a second logic element that is filtered out.

17. A method for data transmission between a first module with a first clock supply unit and a second module with a second clock supply unit, comprising:
providing a start signal at the beginning of a data transmission and in parallel to the data transmission,
wherein the beginning of the start signal is detected and selected.

18. The method according to claim 15, wherein the beginning of the start signal is detected with the leading and trailing clock edge of the second clock supply unit.
